(19) United States
(12) Patent Application Publication
(10) Pub. No.: US 2007/0235133 A1
(43) Pub. Date: Oct. 11, 2007

(54) Devices and methods for measuring wafer characteristics during semiconductor wafer polishing

(75) Inventor: Robert Benassi, San Luis Obispo, CA (US)

Correspondence Address: CROCKETT & CROCKETT, 24012 CALLE DE LA PLATA, SUITE 400, LAGUNA HILLS, CA, 92653, US

(73) Assignee: Strasbaugh

(21) Appl. No.: 11/393,041

(22) Filed: Mar. 29, 2006

(51) Int. Cl. H01L 21/306; C23F 1/00

(52) U.S. Cl. 156/345.12; 156/345.13; 156/345.15; 438/692; 438/693

(57) ABSTRACT

A system and method of measuring a change in thickness of a layer of material disposed on a wafer while polishing the layer. Light is directed at the surface of the wafer from an indwelling optical sensor disposed within a polishing pad and data signals are wireless transmitted to a control system.

### FIELD OF THE INVENTIONS

The present invention is related to the field of semiconductor wafer processing, and more specifically, to a sensor assembly disposed within a disposable polishing pad for use in chemical mechanical polishing. The polishing pad contains a sensor assembly for monitoring wafer characteristics while the polishing operation is taking place, thus permitting the regulation of the process.

### BACKGROUND OF THE INVENTIONS

In U.S. Pat. No. 5,893,796 issued Apr. 13, 1999 and in continuation U.S. Pat. No. 6,045,439 issued Apr. 4, 2000, Birang et al., a number of designs for a window installed in a polishing pad is disclosed. The wafer to be polished is on top of the polishing pad, and the polishing pad rests upon a rigid platen so that the polishing occurs on the lower surface of the wafer. That surface is monitored during the polishing process by an interferometer that is located below the rigid platen. The interferometer directs a laser beam upward, and in order for it to reach the lower surface of the wafer, it must pass through an aperture in the platen and then continue upward through the polishing pad. To prevent the accumulation of slurry above the aperture in the platen, a window is provided in the polishing pad. Regardless of how the window is formed, it is clear that the interferometer sensor is always located below the platen and is never located in the polishing pad.

In U.S. Pat. No. 5,949,927 issued Sep. 7, 1999 to Tang, there are described a number of techniques for monitoring polished surfaces during the polishing process. In one embodiment Tang refers to a fiber-optic ribbon embedded in a polishing pad. This ribbon is merely a conductor of light. The light source and the detector that do the sensing are located outside of the pad. Nowhere does Tang suggest including a light source and a detector inside the polishing pad. In some of Tang's embodiments, fiber-optic decouplers are used to transfer the light in the optical fibers from a rotating component to a stationary component. In other embodiments, the optical signal is detected onboard a rotating component, and the resulting electrical signal is transferred to a stationary component through electrical slip rings. There is no suggestion in the Tang patent of transmitting the electrical signal to a stationary component by means of radio waves, acoustical waves, a modulated light beam, or by magnetic induction.

In another optical end-point sensing system, described in U.S. Pat. No. 5,081,796 issued Jan. 21, 1992 to Schultz there is described a method in which, after partial polishing, the wafer is moved to a position at which part of the wafer overhangs the edge of the platen. The wear on this overhanging part is measured by interferometry to determine whether the polishing process should be continued.

In earlier attempts to mount the sensor in the polishing pad, an aperture was formed in the polishing pad and the optical sensor was bonded into position within the aperture by means of an adhesive. However, subsequent tests revealed that the use of an adhesive could not be depended upon to prevent the polishing slurry, which may contain reactive chemicals, from entering the optical sensor and from penetrating through the polishing pad to the supporting table.

In conclusion, although several techniques are known in the art for monitoring the polished surface during the polishing process, none of these techniques is entirely satisfactory. The fiber optic bundles described by Tang are expensive and potentially fragile; and the use of an interferometer located below the platen, as used by Birang et al., requires making an aperture through the platen that supports the polishing pad. Accordingly, the present invention provides a monitoring system that is economical and robust, taking advantage of recent advances in the miniaturization of certain components. A self-contained sensor assembly disposed within a polishing pad is disclosed. The sensor assembly is placed in wireless communication with the control center simplifying installation on a CMP tool. The sensor assembly may be discarded with the pad or removed and re-installed in subsequent pads.

### SUMMARY

A disposable polishing pad with a sensor assembly is described below. The polishing pad contains a sensor assembly for monitoring, in situ, an optical characteristic of a wafer surface being polished. Other characteristics may also be monitored such as force, acceleration, slurry pH and temperature. The real-time data derived from the optical sensor enables, among other things, the end-point of the process to be determined without disengaging the wafer for off-line testing. This greatly increases the efficiency of the polishing process.

The wafers to be polished are composite structures that include strata of different materials. Typically, the outermost stratum is polished away until its interface with an underlying stratum has been reached. At that point it is said that the end point of the polishing operation has been reached. The polishing pad and accompanying optics and electronics is able to detect transitions from an oxide layer to a silicon layer as well as transitions from a metal to an oxide, or other material.

The polishing pad described involves modifying a conventional polishing pad by embedding within it a sensor assembly and other components. The unmodified polishing pads are widely available commercially, and the Model IC 1000 made by the Rodel Company of Newark, N.J., is a typical unmodified pad. Pads manufactured by the Thomas West Company may also be used.

The sensor assembly senses an optical characteristic of the surface that is being polished. Typically, the optical characteristic of the surface is its reflectivity. However, other optical characteristics of the surface can also be sensed, including its polarization, its absorptivity, and its photoluminescence (if any). Techniques for sensing these various characteristics are well known in the optical arts, and typically they involve little more than adding a polarizer or a spectral filter to the optical system. For this reason, in the following discussion the more general term “optical characteristic” is used.

A sensor assembly that includes a light source and a detector is disposed within a blind hole in the polishing pad so as to face the surface that is being polished. Light from the light source is reflected from the surface being polished or from films near the surface and the detector detects the reflected light. The detector produces an electrical signal related to the intensity or other properties of the light reflected back onto the detector.

The electrical signal produced by the detector is transmitted to a control system within the sensor assembly. The sensor assembly then transmits wafer data wirelessly from the sensor control system to a wireless receiver in wireless communication with a CMP tool control system located outside the sensor assembly.

Electrical power for operating the sensor assembly may be provided by several techniques. In one embodiment of the sensor assembly, electrical power is derived from a battery located within the sensor assembly. In another embodiment, a solar cell or photovoltaic array is mounted within the sensor assembly and is illuminated by a light source mounted on a portion of the machine. In yet another embodiment, electrical conductors in the rotating polishing pad through the magnetic fields of permanent magnets mounted on adjacent non-rotating portions of the polishing machine, to constitute a magneto.

The electrical signal representing wafer data including an optical characteristic of the surface being polished is transmitted from the sensor assembly to an adjacent stationary portion of the polishing machine by any of several techniques. In one embodiment, the wafer data to be transmitted is transmitted wirelessly by radio frequency or by an acoustical link. In another embodiment, the data is used to frequency modulate a light beam such as infrared that is received by a detector located on adjacent non-rotating structure.

There should be an optical path between the top of the sensor and the lower side of the wafer. The signal transmission may be may be from the sensor assembly or by an adjacent separate transmitter also disposed within the pad and operably connected to the sensor assembly.

### BRIEF DESCRIPTION OF THE DRAWINGS

FIG. 1 shows a top view of a chemical mechanical planarization machine polishing wafers using a polishing pad embedded with a sensor assembly having optical sensors.

FIG. 2 is an exploded view in perspective showing the general arrangement of the elements of the sensor assembly as placed in a polishing pad.

FIG. 3 is a front top perspective view of the sensor assembly.

FIG. 4 is a block diagram of the sensor assembly.

FIG. 5 is a side elevational diagram showing a sensor assembly having an optical sensor without a prism.

FIG. 6 illustrates a sensor assembly in the shape of a thin disk.

FIG. 7 illustrates a sensor assembly in the shape of a spool.

FIG. 8 shows a sensor assembly with a transmitter that includes a modulator that applies to a light emitting diode or laser diode a frequency modulated current representative of the processed signal that represents the optical characteristic.

FIG. 9 shows the sensor assembly 25 with a radio transmitter.

FIG. 10 shows the sensor assembly 25 having a transmitter that produces sound waves.

FIG. 11 shows a detailed view of the overall polishing pad, installed in a CMP system, using a sensor assembly.

FIG. 12 shows a detailed view of the polishing pad installed in a CMP system with a sensor assembly and a central hub.

FIG. 13 is a block diagram of the sensor assembly with a central hub.

FIG. 14 illustrates the behavior of light of a selected wavelength when the light is incident on a thin layer of material disposed on the front side of a wafer.

FIG. 15 is a graph of the intensity of the detected light over time as the first layer of material is removed from a wafer.

### DETAILED DESCRIPTION OF THE INVENTIONS

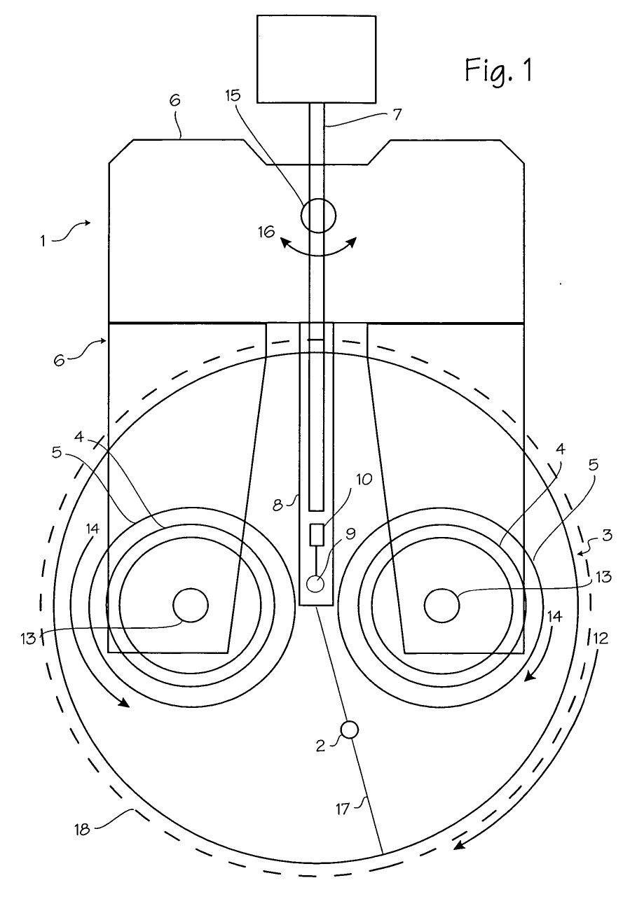

FIG. 1 is an overhead view of a chemical mechanical planarization system 1 with the sensor port 2 cut into the polishing pad 3. The wafer 4 (or other work piece requiring planarization or polishing) is held by the polishing head 5 and suspended over the polishing pad 3 from a translation arm 6. Other systems may use several polishing heads that hold several wafers, and separate translation arms on opposite sides (left and right) of the polishing pad.

The slurry used in the polishing process is injected onto the surface of the polishing pad through slurry injection tube 7. The suspension arm 8 having a wireless transceiver 9 in electrical communication with a CMP data collection and control system 10 for the CMP system 1 suspends over the pad 3.

The sensor port rotates with the polishing pad, which itself rotates on a process drive table, or platen 18, in the direction of arrow 12. The polishing heads rotate about their respective spindles 13 in the direction of arrows 14. The polishing heads themselves are translated back and forth over the surface of the polishing pad by the translating mechanism 15, as indicated by arrow 16. Thus, the sensor port 2 passes under the polishing heads while the polishing heads are both rotating and translating, swiping a complex path across the wafer surface on each rotation of the polishing pad/platen assembly. The sensor port 2 remains on the same radial line 17 as the pad rotates. However, the radial line translates in a circular path as pad 3 rotates.

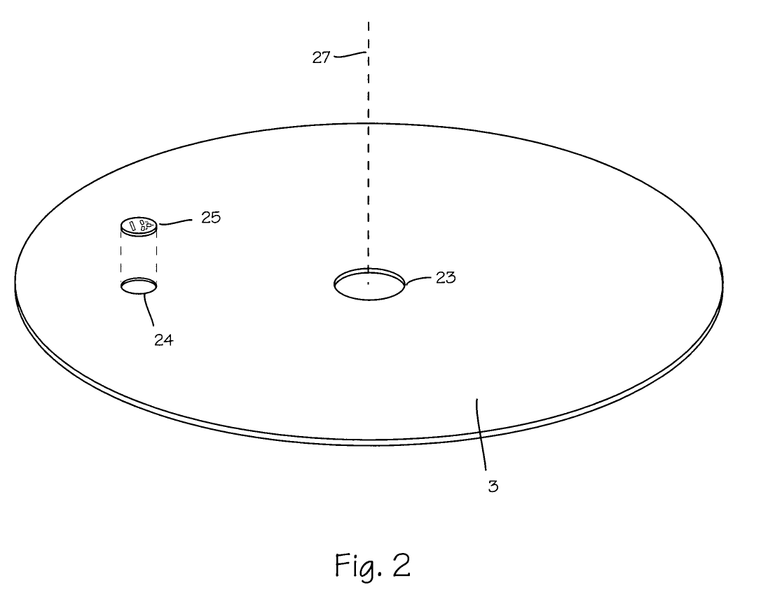

As shown in FIG. 2, the polishing pad 3 has a circular shape and may be provided with a central circular aperture 23. A blind hole or through-hole 24 is formed in the polishing pad to form the sensor port 2, and the hole opens upwardly so as to face the surface that is being polished creating the sensor port. A sensor assembly 25 is placed in the blind hole 24 and disposed within the polishing pad 3. The sensor assembly may be releasably attached to the pad. Releasably attached can be defined as adapted to be coupled and uncoupled without use of tooling. During the polishing process, the polishing pad 3 rotates about a central vertical axis 27.

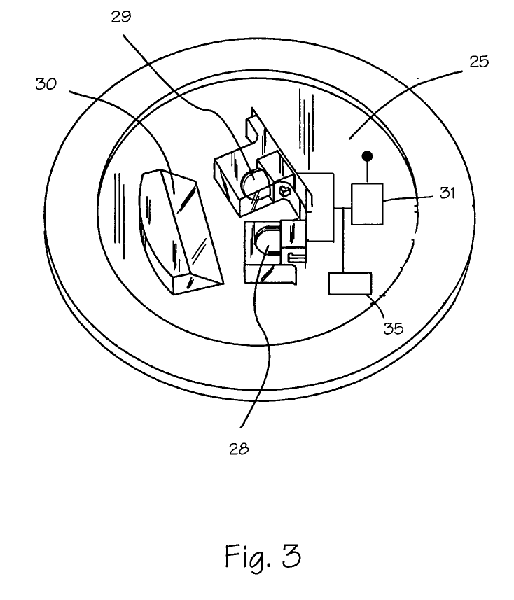

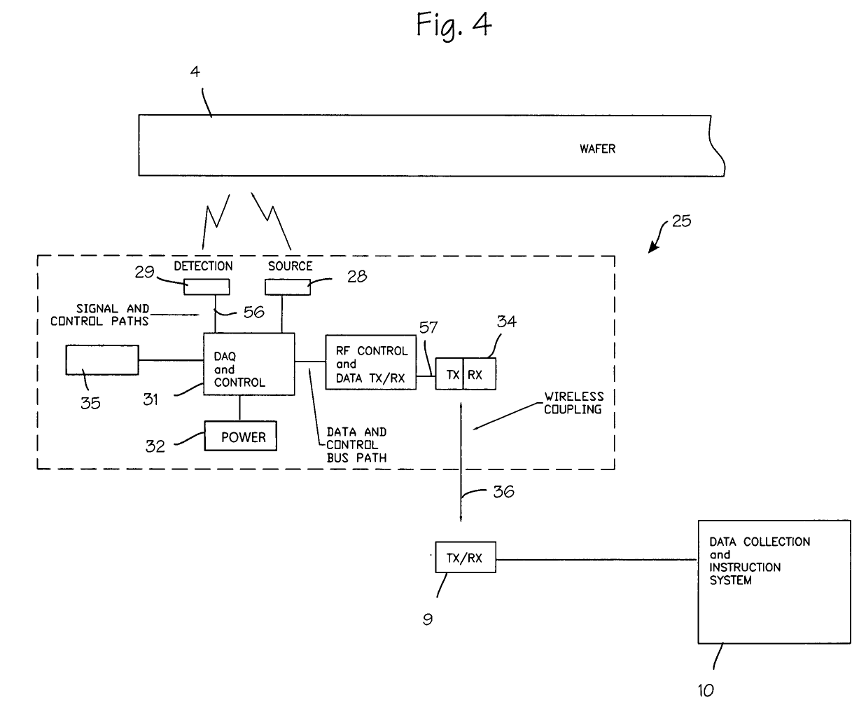

FIG. 3 shows the self-contained sensor assembly 25 in greater detail while FIG. 4 a shows block diagram of the sensor assembly. The sensor assembly 25 components include a light source 28, a detector 29, a reflective surface 30 (which could be a prism, mirror, or other reflective optical component), a sensor control system 31 having a data acquisition chip and a signal processor, a power source 32, a wireless transmitter 33 and a wireless receiver 34. The power source supplies electrical power to the light source 28 and the control system and preferably comprises a battery. However, the power source 32 may also comprise a capacitor, a magnetic induction system, a pressure generated power system or an optical generated power system. In some alternative power sources, energy may be transferred from a source embedded in the table or near the table surfaces to the sensor assembly. The sensor assembly may also be provided with a variety of other sensors 35 including a pH sensor for taking pH measurements, a thermocouple for taking temperature measurements, a pressure transducer for taking force measurements, an accelerometer for taking acceleration measurements and an eddy current probe for taking eddy current measurements. The sensors may be manufactured using micro electrical mechanical system (MEMS) technology, micro optical electrical systems (MOEMS) and electrode-based technologies.

The sensor assembly can be provided without components such as the light source 28, the detector 29, and the reflective surface 30, but rather provided with only a single dedicated sensor 35. A dedicated sensor may include a pH sensor for taking pH measurements, a thermocouple for taking temperature measurements, a pressure transducer for taking force measurements, an accelerometer for taking acceleration measurements or an eddy current probe for taking eddy current measurements.

The wireless transmitter and receiver may use any suitable wireless protocol, but preferably uses radio frequency for the purpose of transmitting and receiving data signals 36 between the sensor control system and a CMP data collection and control system. Alternatively to radio frequency, the sensor assembly could be supplied with an infrared (IR) transmitter and receiver for sending and receiving data in the IR range. The sensor assembly may be a passive system, semi-passive system or active system. In a passive sensor assembly, the minute electrical current induced in an antenna within the sensor assembly by the incoming radio frequency signal provides enough power for the integrated circuit (IC) in the control system in the sensor assembly to power up and transmit a response. Passive systems signal by backscattering the RF signal from the CMP tool control system. This means that the antenna in the sensor assembly is designed to both collect power from the incoming signal and also to transmit an outbound data signal. The response of a passive system contains data signals reflective of wafer characteristics.

Semi-passive sensor assemblies 25 are very similar to passive sensor assemblies except for the addition of a battery. The battery allows the sensor assembly to be constantly powered. This removes the need for the antenna to be designed to collect power from the incoming signal. The antenna can therefore be optimized for sending the data signal.

Active sensor assemblies 25, like the one illustrated in FIG. 3, have their own internal power source 32 which is used to power the sensor control system 31, sensors 35 and generate the outgoing data signal. Because the active sensor assembly 25 contains its own power source, it can have a longer range and a larger memory than a passive sensor assembly 25, as well as the ability to store additional information sent by the CMP tool control system. To economize power consumption, the active sensor assembly may be programmed to operate at fixed intervals.

The data signal sent by the sensor assembly is available for use by external circuitry of the CMP tool data collection and control system operably connected to a wireless transmitter and receiver for such purposes such as monitoring the progress of the polishing operation or determining whether the end point of the polishing process has been reached. The data signal can contain a word value of digital bytes or could be a simple change in frequency output that may be interpreted by the CMP tool control system. The data being sent via a data signal by the sensor control system in the sensor assembly may include data corresponding to reflection of light and color from a wafer surface, surface finish or smoothness, acceleration, vibration, force or pressure, temperature, slurry pH, table velocity, table run-out, Eddy current to indicate metal film thickness, resistance, pad wear, pad status, moisture in/on pad, remaining average film thickness, uniformity of remaining films feature height detection, retaining ring wear, conditioning disk pressures, wafer location(s) and particles in the slurry. The sensor control system conducts measurements at appropriate times, identifies and stores the location of the wafer during the sensing of data and transmits the data to a receiver outside the pad. Data transfer may be conducted continuously, passively or on request by the CMP tool control system. Data transfer may be performed uni-directionally from the sensor assembly to the CMP tool control system when the sensor assembly is merely supplied with a transmitter. Data transfer can also be performed bi-directionally between the sensor assembly and the CMP tool control system when the sensor assembly is supplied with a transmitter and receiver. Data is used by the CMP data collection and control system to adjust polishing parameters during polishing in real-time or determine if polishing is complete. Thin wafer uniformity control may be facilitated by adjusting backpressure in response to data collected. Run-to-run control can also be facilitated by adjusting polishing parameters between wafers.

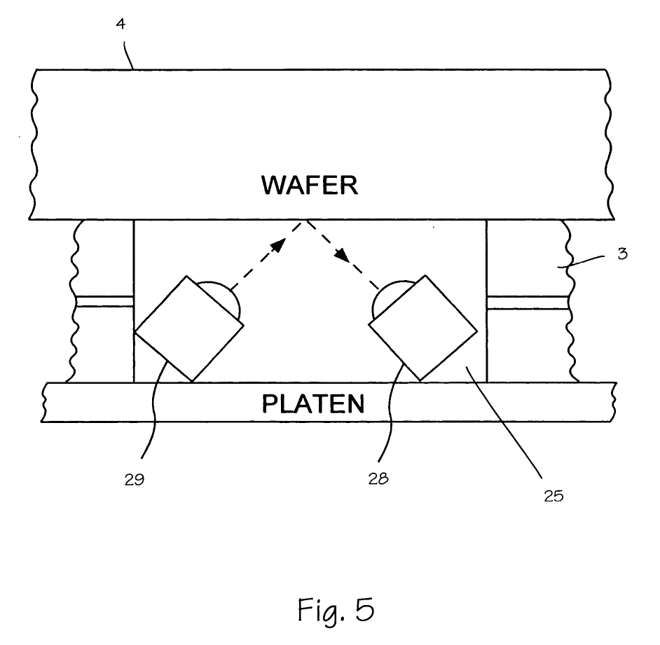

The light source 28 and the detector 29 are a matched pair. In general, the light source 28 is a light emitting diode and the detector 29 is a photodiode. The central axis of the beam of light emitted by the light source 28 is directed horizontally initially, but upon reaching the reflective surface 30 the light is redirected upward so as to strike and reflect from the surface that is being polished. The reflected light also is redirected by the reflective surface 30 so that the light reflected from the wafer falls on the detector 29, which produces an electrical signal in relation to the intensity of the light falling on it. The arrangement shown in FIG. 3 was chosen to minimize the height of the sensor. The reflective surface 30 may be omitted and instead the arrangement shown in side view in FIG. 5 may be used. The detector is used to determine the intensity and color of reflected light from the wafer surface.

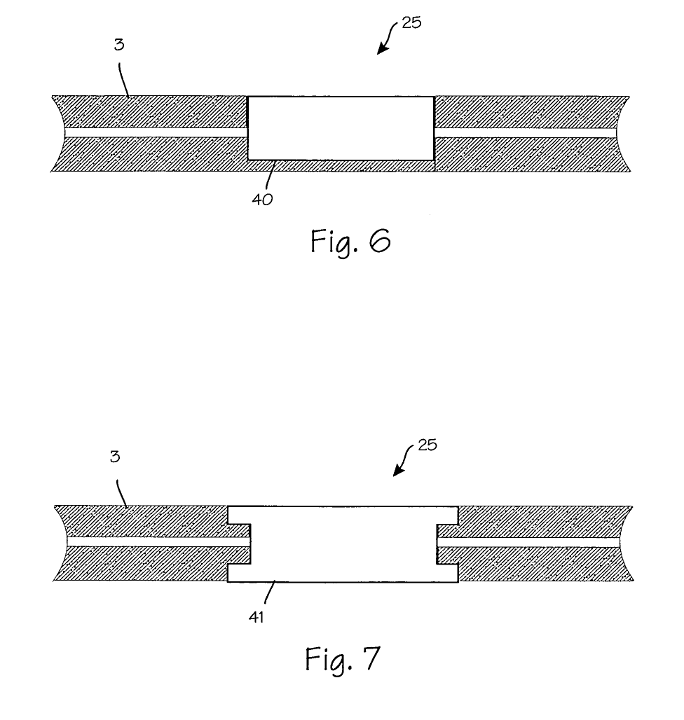

As shown in FIG. 6, the sensor components of the sensor assembly are encapsulated within a housing in the form of a thin disk 40 or puck that is sized to fit snugly within the blind hole 24 of FIG. 2. As illustrated in FIG. 7, sensor components may also be encapsulated in a spool-shaped 41 housing or other various shaped housings sized and dimension to secure the sensor assembly to the pad, prevent the sensor assembly from moving during polishing and allow the sensor assembly to obtain wafer data as shown in FIG. 4. Baffles may be used to reduce the amount of scattered or ambient light reaching the detector 29. The housing may be comprised of molded glass or a polymer such as urethane. The housing may extend through the entire pad as shown in FIG. 7. The housing may also be embedded in a blind hole that does not extend through the entire pad as shown in FIG. 6. The housing is manufactured from a material adapted to transport the light wavelength used by the sensor assembly which may include infrared light, visible light or ultra violet light.

The sensor assembly may be manufactured using the techniques disclosed in our U.S. Pat. No. 6,986,701, the contents of which are incorporated in its entirety by reference. For example, an aperture, or hole, may be produced in the polishing pad. The aperture must be large enough to accommodate the components of the sensor assembly or the sensor assembly encapsulated in a housing. The components may be placed into a disk or puck so that it may be easily disposed into the aperture. Portions of the aperture adjacent to the upper surface and lower surface of the polishing pad may extend a short distance radially outward from a through hole. This creates a spool-shaped void with the boundaries of the pad. In another method of manufacure, the sensor assembly components may be disposed within an aperture in the pad and overmolded with a polymer.

After the aperture has been formed in the polishing pad, a sensor assembly or its components are inserted into their respective places, where they are supported and held in place by spacers composed of urethane or by portions of the upper layer and lower layer. Thereafter, the assembly is placed into a fixture that includes flat, non-stick surface. The non-stick surfaces and are brought into contact with the upper pad surface and lower pad surface and pressed together. Liquid urethane is then injected to form the housing. Other techniques of manufacture and assembly include creating an aperture, or hole, in the polishing pad, disposing a self-contained sensor assembly with in the hole and coupling a self-contained sensor assembly in the hole with an adhesive material. The pad may also be assembled by creating an aperture, or hole, in the polishing pad, disposing a snap ring sized and dimensioned to accommodate a self-contained sensor assembly in the hole and coupling the snap ring sized to the pad with an adhesive material.

When the sensor assembly is in use, an electrical signal produced by the detector and related to the optical characteristic is carried by the conductor 56 from the detector to a data acquisition and signal processing circuit in the control system, that produces, in response to the electrical signal, a processed data signal representing the optical characteristic. The processed signal is sent by conductor 57 to a transmitter. The transmitter then sends the data signal wirelessly to a receiver operably connected to the CMP data collection and control system. Thus, the sensor assembly and CMP data collection and control system are in wireless communication with one another.

The CMP data collection and control system is able to use data from the data signal to regulate the CMP process. Force(s) being applied to the wafer by the CMP system, the amount of slurry, temperature of the slurry, the pressure at which the slurry is applied and the speed of rotation can be regulated based on the data signal. For instance, if the data signal indicates the temperature of the slurry is excessive, the wafer is being polished at a rate that is outside an acceptable threshold or the amount of material removed by polishing has reached a target removal thickness, the pressure being applied by the translation arm to the wafer can be reduced by the CMP data collection and control system.

FIGS. 8 through 10 show other various techniques that may be used to transfer data signals from the sensor assembly 25 to the polishing machine and to transfer electrical power from the polishing machine to the sensor assembly.

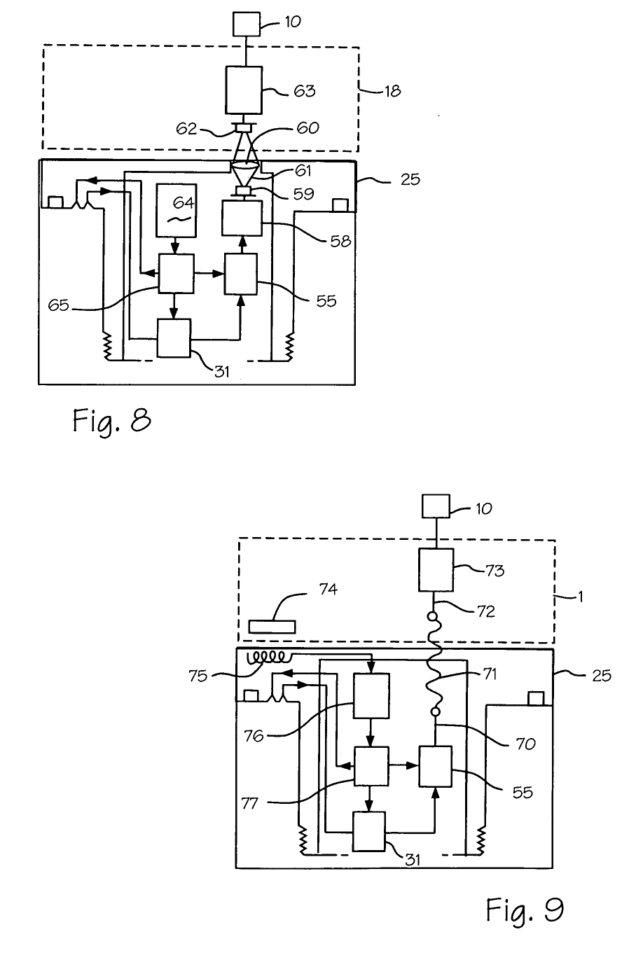

FIG. 8 shows a sensor assembly having a transmitter 55 that includes a modulator 58 that applies to a light emitting diode or laser diode 59 a frequency modulated current representative of the processed signal that represents the optical characteristic. The light-emitting diode emits light waves 60 that are focused by a lens 61 onto a photodiode detector 62 disposed in the platen 18 below the sensor assembly 25. The detector 62 converts the light waves 60 into an electrical signal that is demodulated in the receiver 63 to produce on the CMP control system 10 an electrical signal representative of the optical characteristic. The prime source of electrical power is a battery 64 or other energy source that supplies power to a power distribution circuit 65 that, in turn, distributes electrical power to the signal processing circuit and to the transmitter circuit. In FIG. 9, the sensor assembly 25 has a transmitter that is a radio transmitter having an antenna 70 that transmits radio waves 71. The radio waves 71 are intercepted by the antenna 72 and demodulated by the receiver 73 to produce an electrical signal on the terminal that is representative of the optical characteristic.

Electrical power is generated by a magneto consisting of a permanent magnet 74 located in a non-rotating portion of the CMP system 1 and an inductor 75 in which the magnetic field of the permanent magnet 74 induces a current as the inductor 75 rotates past the permanent magnet 74. The induced current is rectified and filtered by the power circuit 76 and then distributed by a power distribution circuit 77.

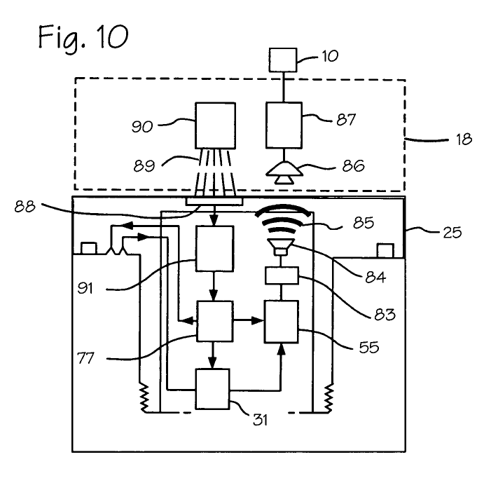

In FIG. 10, the sensor assembly 25 has a transmitter that includes a power amplifier 83 that drives a loudspeaker 84 that produces sound waves 85. The sound waves 85 are picked up by a microphone 86 located in the platen of the polishing machine. The microphone 86 produces an electrical signal that is applied to the receiver 87 which, in turn, produces an electrical signal on the CMP control system 10 that is representative of the optical characteristic.

Electrical power is generated in the sensor assembly by a solar cell or solar panel 88 in response to light 89 applied to the solar panel 88 by a light source 90 located in the platen. The electrical output of the solar panel 88 is converted to an appropriate voltage by the converter 91, if necessary, and applied to the power distribution circuit 77.

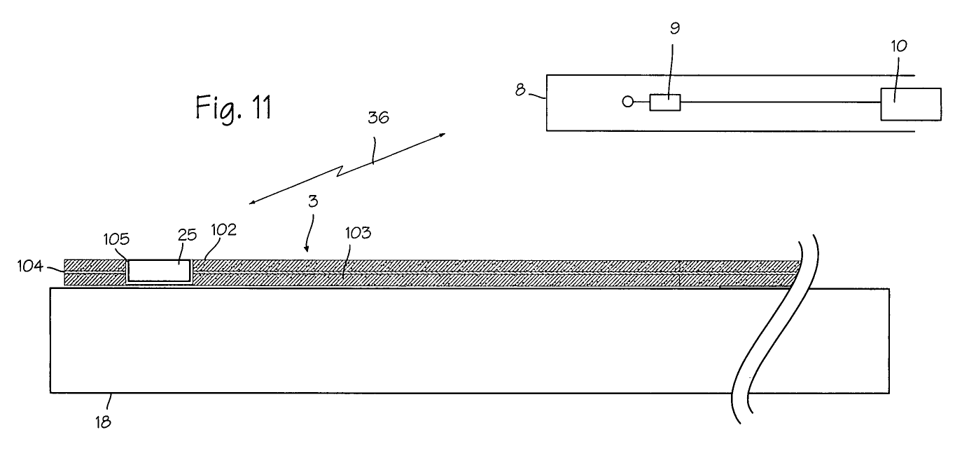

FIG. 11 shows a detailed view of the overall polishing pad 3, installed in a CMP system, using a sensor assembly 25. The polishing pads shown are typical polishing pads available in the industry, such as the model IC 1000 produced by Rodel Co. The model comprises two 0.045-inch thick layers of foamed urethane bonded face to face by a 0.007-inch thick layer of adhesive. The pad comprises the upper pad layer 102, lower pad layer 103, adhesive layer 104 and a sensor assembly 25, described in the previous Figures. The pad is placed on and attached to the platen 18. The sensor assembly is inserted, for example, into a snap ring 105. After extended use, the pad will be exhausted and may be removed and discarded. A new pad may be placed on the platen, and the sensor assembly may be inserted into the snap ring of the new pad.

As illustrated in FIG. 11, the sensor assembly is placed in wireless communication with the CMP tool control system. Data signals containing data such as reflection of light and color from a wafer surface, acceleration of the platen, vibration of the platen, force or pressure applied by the CMP tool to the wafer, temperature of the slurry, slurry pH, table velocity, table run-out, Eddy current to indicate metal film thickness, resistance, pad wear, pad status, moisture in/on pad, remaining average film thickness, uniformity of remaining films feature height detection, retaining ring wear, conditioning disk pressures, wafer location(s) and particles in the slurry are transmitted between the sensor assembly and the CMP tool control system.

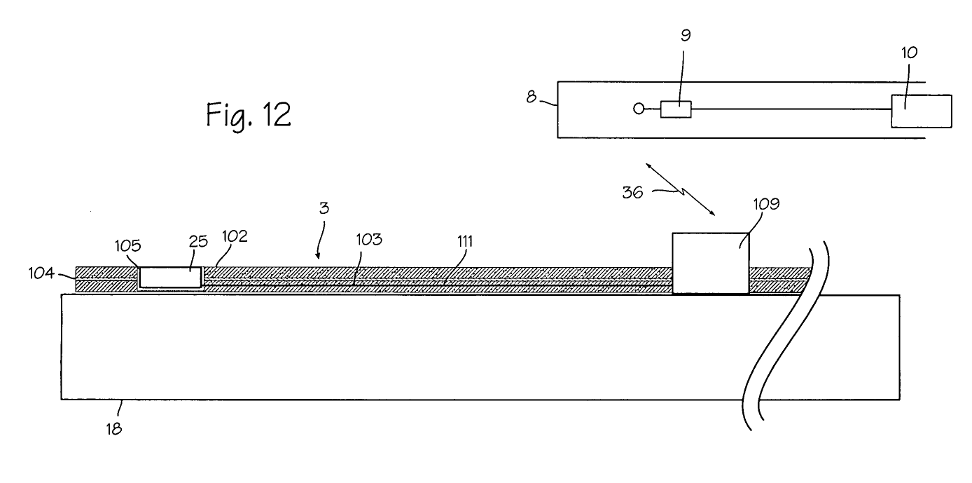

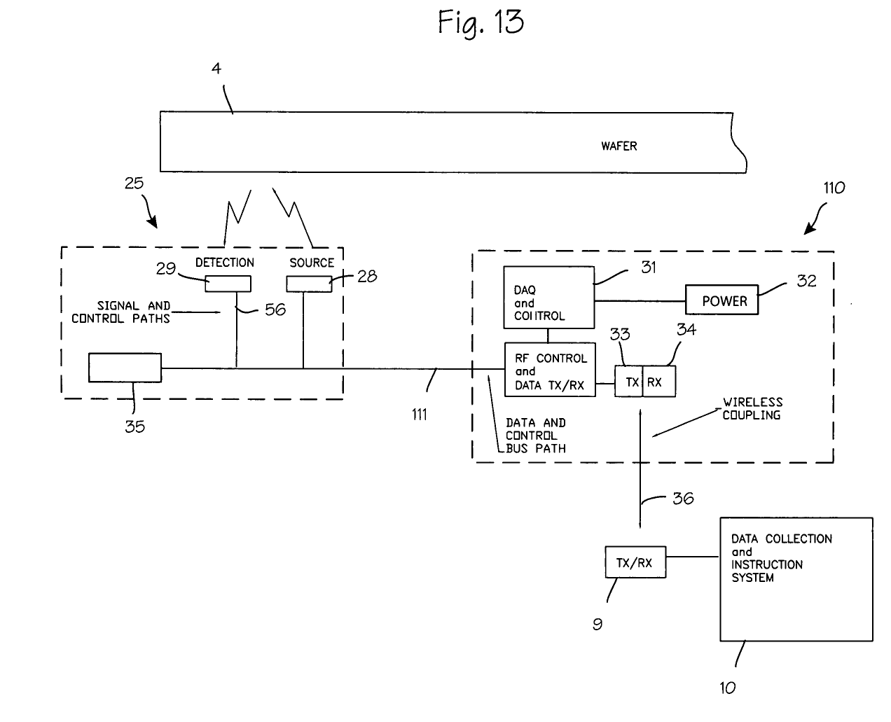

FIG. 12 illustrates a sensor assembly placed in electrical communication with a central rotating hub and FIG. 13 a shows block diagram of the sensor assembly with the central hub. In this embodiment, the central hub 109 contains the power source 32, the sensor control system 31 and wireless transmitter 33 and receiver 34. The sensor assembly having sensors 35 is place in electrical communication with the central hub by a ribbon cable 111 disposed within the center or the pad 3.

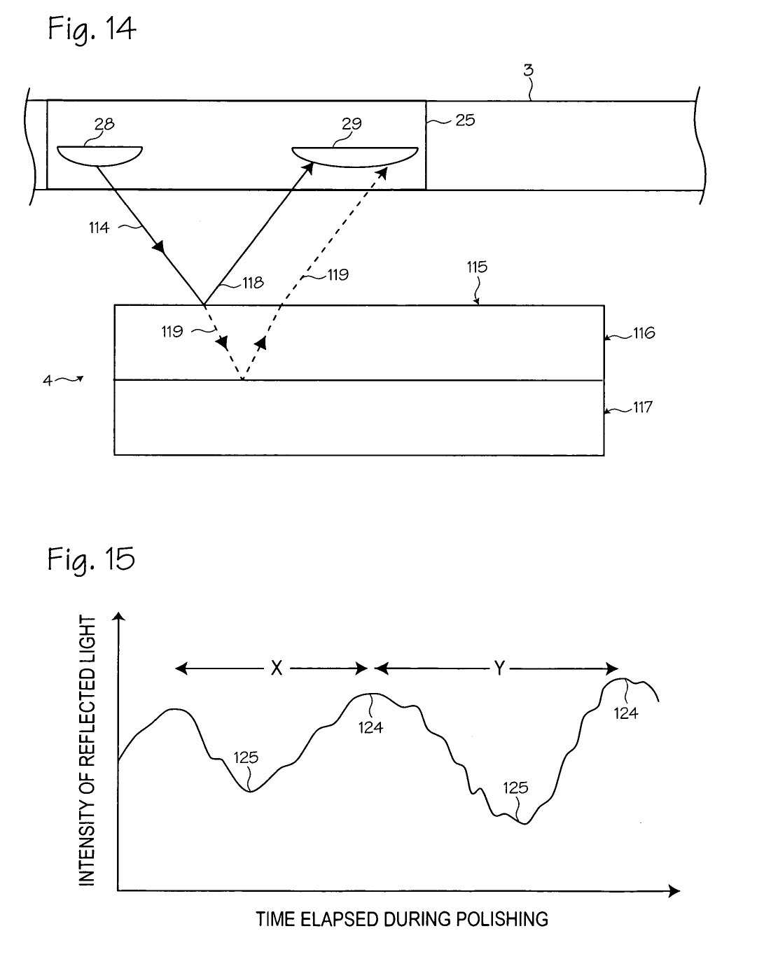

FIG. 14 illustrates the behavior of light 114 of a selected wavelength when the light is incident on a thin layer of material disposed on the front side of a wafer. The wafer 4 is greatly magnified to show the two outermost layers built up on the front side 115 of the wafer. The first, outermost, layer 116 covers the second layer 117. Each layer may have a thickness of about 30 micrometers or less, usually between about 10 micrometers and about 1,000 Angstroms (about 1/10 of a micrometer), and a plurality of additional layers may be disposed beneath the first and second layers. During the polishing process the first layer is polished to remove the layer either partially or completely. To determine how much of the first layer has been removed, light 114 of a selected wavelength is emitted from the light source 28 and directed at the front side of the wafer at a fixed angle relative to the axis of the sensor assembly. The reflected light is detected by the detector 29. Both the light source and light detector are disposed within the sensor assembly and the sensor assembly may be disposed completely within the polishing pad. The intensity of the light reflected from the wafer conveys information regarding the amount of material removed during polishing. (The wavelength of the light is selected so that a portion of the light will transmit through the thin layer of material. For many layer materials, such as silicon, silicon dioxide, copper and other materials, the wavelength selected is in the range of about 300 nanometers (blue light) or less to about 1500 nanometers or more (infrared light). The angle of incidence and reflection is fixed between about 0 degrees and 70 degrees, preferably about 5 degrees, as measured between the axis of the puck and the light source.)

When light 114 is directed onto the front side of the wafer, a portion 118 of the light reflects from the surface of the wafer and a portion 119 of the light passes through the surface and through the first layer 116 of material. Portion 119 of the light reflects from the surface of the second layer 117 and escapes through the first layer 116. Portion 118 and portion 119 combine together before reaching the detector. Because portion 119 travels a greater distance than portion 118, the light reflected from the surface of the first layer 116 (portion 118) and the light reflected from the surface of the second layer 117 (portion 119) may be out of phase. Depending on the relative phase of portions 118 and 119, the two portions either constructively or destructively interfere with each other, thereby causing the detected light to become either more or less intense, respectively.

As the first layer 116 is removed, the distance traveled by portion 119 relative to portion 118 changes, thereby changing their phase relationship. As a result, the intensity of the detected light changes as the first layer is removed. As the phase shift between the two light rays repeatedly varies between 0 and 90 degrees as the layer is removed, the intensity of the detected light varies approximately sinusoidally.

FIG. 15 is a graph of the intensity of the detected light over time as the first layer of material is removed from a wafer. (The intensity of the reflected light is a function of layer thickness and sinusoidally varies with layer thickness. Layer thickness varies over the time of polishing.) When light portion 118 and light portion 119 completely constructively interfere with each other, the intensity of the detected light is at a peak 124. When light portion 118 and light portion 119 completely destructively interfere with each other, the intensity of the detected light is at a trough 125.

To measure the amount of material removed during polishing, the curve must be calibrated. To calibrate the sinusoidal curve, the absolute thickness of the outer layer is first measured by spectral reflectance, ellipsometry or other technique for measuring absolute thickness. (These techniques may be performed using equipment provided by a variety of vendors. The equipment is relatively bulky, expensive or delicate and slurry and other aspects of the polishing process interfere with precise measurements of the index of refraction and of layer thickness. Thus, these other techniques for measuring layer thickness are not practical for use within a polishing pad during polishing or for use during mass production.) Next, the intensity of the reflected light signal is measured with the sensor assembly 25. The outer layer of a test wafer is then polished until one or more wavelengths of the sinusoidal curve is measured or observed. Thus, if the initial intensity of the reflected light was at a peak or trough, then the wafer is polished until a second or subsequent peak or trough is measured. If the initial intensity of the reflected light signal was at some other point on the sinusoidal curve, then the wafer is polished until the same intensity is measured two or more times. The polishing process is then stopped and the absolute thickness of the outer layer is measured again.

The difference between the two measurements of layer thickness is the initial change in layer thickness. The initial change in layer thickness is also represented by one wavelength along the sinusoidal curve, but only if using the same polishing process on the same kind of wafer (or outer wafer layers) and if using the same wavelength of incident light. Multiple wavelengths along the curve may be counted, in which case the total change in layer thickness is the number of wavelengths measured times the initial change in layer thickness.

For convenience, wavelengths along the sinusoidal curve may be easily counted by counting the number of peaks or the number of troughs measured during a polishing process. Since the peaks or troughs may be thought of as nodes on the sinusoidal curve, this process of measuring layer thickness may be referred to as node counting. (The term node counting refers to the process of counting wavelengths along a sinusoidal reflectance curve and is not limited to counting only peaks and troughs.)

For example, the outer layer of a wafer is 10,000 Angstroms (1 micrometer) thick, as measured using ellipsometry. The layer is polished using a particular process until one wavelength on the sinusoidal curve is measured. After polishing the layer thickness is 8,000 Angstroms thick, as measured using ellipsometry. Thus, the distance between peaks on the sinusoidal curve (one wavelength) corresponds to a change in layer thickness equal to 2,000 Angstroms. If the final desired thickness of the layer is 4,000 Angstroms, the layer is polished until a total of 3 wavelengths are counted (representing 6,000 Angstroms of removed material), at which point the polishing process reaches its endpoint.

This process may also be used to continuously measure smaller changes in layer thickness. A fraction of a wavelength along the sinusoidal curve equals a corresponding fractional change in the thickness of the polished layer. Continuing the above example, ½ of the wavelength (the peak-to-peak distance shown by arrows “X”) represents a change in layer thickness equal to 1,000 Angstroms. Thus, if the wafer is polished again and another half wavelength along the sinusoidal curve is measured, then the final layer thickness will be 3,000 Angstroms. Since fractions of a wavelength can be counted, node counting may make in-situ measurements of very small changes in layer thickness.

Calibrating the sinusoidal curve at many points along the curve or over multiple wavelengths may be necessary where the wavelength of the curve varies over the time of polishing and where the different wavelengths represent different amounts of material removed. Thus, as shown in FIG. 15, when the distance along arrows “X” does not equal the distance along arrows “Y”, then more of the sinusoidal curve may have to be calibrated. In addition, the absolute thickness of the layer may be measured at any number of points along the sinusoidal curve to increase the precision of the calibration curve. This may be necessary if the sinusoidal curve is subject to noise, represented by the variations in the sinusoidal curve shown in FIG. 15.

A processor and software are provided to correlate the change in intensity of reflected light to the change in layer thickness according to the above methods. A display may be provided to display the progress of the polishing process. A control system, such as computer hardware and software, may be provided to modify the polishing process or to slow, stop or otherwise change the rate of polishing in response to a change in the layer thickness. Thus, the CMP control system may cause polishing to slow as the endpoint of a process is neared and stop when the endpoint is reached. (The control system can control any aspect of the polishing process in response to the change in layer thickness over time.)

Libraries of sinusoidal reflectance curves may be generated to save time during production. Each curve will be the same for a particular process on a particular wafer. Thus, when polishing a known type of wafer with a known process for which a calibration curve has already been established, the calibration step may be skipped. In addition, each reflectance curve may be further refined by measuring the absolute thickness of each layer removed for each wavelength counted over the entire polishing process. Thus, the calibration curve will be precise over the entire duration of a polishing process (regardless of changes in index of refraction, layer materials or in processing parameters).

Thus, while the preferred embodiments of the devices and methods have been described in reference to the environment in which they were developed, they are merely illustrative of the principles of the inventions. Other embodiments and configurations may be devised without departing from the spirit of the inventions and the scope of the appended claims.

1. A system for measuring a change in wafer characteristics while said wafer is polished, said system comprising:
a polishing pad suitable for polishing the wafer;
a light source disposed within the pad;
a light detector disposed within the pad;
a wireless transmitter disposed within the pad; and
a sensor control system disposed within the pad, said sensor control system operably connected to the light source, the light detector and the wireless transmitter.

2. The system of claim 1 further comprising a wireless receiver disposed within the pad operably connected to the sensor control system.

3. The system of claim 1 further comprising a power supply operably connected to the sensor control system.

4. The system of claim 1 further a force transducer disposed within the pad operably connected to the sensor control system.

5. The system of claim 1 further comprising an accelerometer disposed within the pad operably connected to the sensor control system.

6. The system of claim 1 further comprising a pH sensor disposed within the pad operably connected to the sensor control system.

7. The system of claim 1 further comprising a thermocouple disposed within the pad operably connected to the sensor control system.

8. The system of claim 1 further comprising a CMP control system in wireless communication with the sensor control system, said CMP control system operably connected to a CMP tool and capable of controlling a rate of polishing of the CMP tool when a predetermined wavelength of light is measured.

9. A system for measuring a change in wafer characteristics while said wafer is polished, said system comprising:
a polishing pad suitable for polishing the layer; and
a sensor assembly disposed within the polishing pad, said sensor assembly comprising:
a housing;
a sensor control system disposed within the housing;
a light source disposed within the housing and operably connected to the control system;
a light detector disposed within the housing and operably connected to the sensor control system; and
a wireless transmitter disposed within the housing and operably connected to the sensor control system.

10. The system of claim 9 wherein the sensor assembly is removably coupled to the pad.

11. The system of claim 9 further comprising a wireless receiver disposed within the housing and operably connected to the sensor control system.

12. The system of claim 9 further comprising a power supply operably connected to the sensor assembly.

13. The system of claim 9 wherein the housing is in the shape of a disk.

14. The system of claim 9 wherein the housing is in the shape of a spool.

15. The system of claim 9 wherein the sensor assembly further comprises a force transducer disposed within the housing and operably connected to the sensor control system.

16. The system of claim 9 wherein the sensor assembly further comprises an accelerometer disposed within the housing and operably connected to the sensor control system.

17. The system of claim 9 wherein the sensor assembly further comprises a pH sensor disposed within the housing and operably connected to the sensor control system.

18. The system of claim 9 wherein the sensor assembly further comprises a thermocouple disposed within the housing and operably connected to the sensor control system.

19. The system of claim 9 further comprising a CMP control system in wireless communication with the sensor assembly and operably connected to a CMP tool, said CMP control system capable of controlling a rate of polishing of the CMP tool when a predetermined wavelength of light is measured.

20. The system of claim 9 wherein the sensor assembly is characterized by an outer surface facing outwardly from the pad, said outer surface being substantially flush with an outer surface of the polishing pad.

21. A sensor for use in a CMP polishing pad, said system comprising:
an optically transparent housing;
a sensor control system disposed within the housing;
a light source disposed within the housing and operably connected to the control system;
a light detector disposed within the housing and operably connected to the control system; and
a wireless transmitter disposed within the housing and operably connected to the control system;
wherein the housing is capable of being releasably coupled to a CMP polishing pad.

22. The sensor assembly of claim 21 further comprising a wireless receiver disposed within the housing and operably connected to the sensor control system.

23. The sensor assembly of claim 21 a power supply operably connected to the sensor assembly.

24. The sensor assembly of claim 21 wherein the housing is in the shape of a disk.

25. The sensor assembly of claim 21 wherein the housing is in the shape of a spool.

26. The sensor assembly of claim 21 further comprising a force transducer disposed within the housing and operably connected to the control system.

27. The sensor assembly of claim 21 further comprising an accelerometer disposed within the housing and operably connected to the sensor control system.

28. The sensor assembly of claim 21 further comprising a pH sensor disposed within the housing and operably connected to the sensor control system.

29. The sensor assembly of claim 21 wherein further comprising a thermocouple disposed within the housing and operably connected to the sensor control system.

30. The sensor assembly of claim 12 wherein the power source comprises a battery.

31-39. (canceled)
